(19) United States
(12) Patent Application Publication
(10) Pub. No.: US 2025/0175139 A1
(43) Pub. Date: May 29, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Sho NAGATOMO, Nagaokakyo-shi (JP)

(21) Appl. No.: 19/036,134

(22) Filed: Jan. 24, 2025

Related U.S. Application Data
(63) Continuation of application No. PCT/JP2023/030815, filed on Aug. 25, 2023.
(60) Provisional application No. 63/401,244, filed on Aug. 26, 2022.

(51) Int. Cl. H03H 9/02; H03H 9/13; H03H 9/17

(52) U.S. Cl. CPC H03H 9/02086; H03H 9/02031; H03H 9/02157; H03H 9/02228; H03H 9/132; H03H 9/173; H03H 9/175; H03H 9/176

(57) ABSTRACT

An acoustic wave device includes a piezoelectric substrate that includes a support including a support substrate and a piezoelectric film including a piezoelectric layer on the support, and an IDT electrode, on the piezoelectric layer, that includes first and second busbars facing each other, and first and second electrode fingers. An acoustic reflection portion is located where the support overlaps the IDT electrode in plan view. When a thickness of the piezoelectric film is d and a center-to-center distance between the first and second electrode fingers adjacent to each other is p, d/p is about 0.5 or less. An overlap region is where the first and second electrode fingers adjacent to each other overlap in an electrode finger orthogonal direction and includes a middle region, and first and second edge regions on both sides of the middle region in an electrode finger extension direction.

### CROSS REFERENCE TO RELATED APPLICATIONS

This application claims the benefit of priority to Provisional Application No. 63/401,244 filed on Aug. 26, 2022 and is a Continuation application of PCT Application No. PCT/JP2023/030815 filed on Aug. 25, 2023. The entire contents of each application are hereby incorporated herein by reference.

### BACKGROUND OF THE INVENTION

### 1. Field of the Invention

The present invention relates to acoustic wave devices.

### 2. Description of the Related Art

Conventionally, acoustic wave devices have been widely used in filters of mobile phones and the like. In recent years, acoustic wave devices using a bulk wave in a thickness-shear mode, as described in U.S. Pat. No. 10,491,192, have been proposed. In such an acoustic wave device, a piezoelectric layer is provided on a support body. Pairs of electrodes are provided on the piezoelectric layer. Each pair of electrodes faces each other on the piezoelectric layer and is connected to different potentials. A bulk wave in the thickness-shear mode is excited by an AC voltage being applied between the electrodes described above.

### SUMMARY OF THE INVENTION

In an acoustic wave device that uses a bulk wave in the thickness-shear mode as described in U.S. Pat. No. 10,491,192, an unnecessary wave is generated at frequencies close to and lower than a resonant frequency. Accordingly, electrical characteristics may be degraded.

Example embodiments of the present invention provide acoustic wave devices that each reduce or prevent an unnecessary wave at frequencies close to and lower than a resonant frequency.

An acoustic wave device according to an example embodiment of the present invention includes a piezoelectric substrate that includes a support including a support substrate, and a piezoelectric film including a piezoelectric layer provided on the support, and an IDT electrode, provided on the piezoelectric layer, that includes a first busbar and a second busbar that face each other, a plurality of first electrode fingers, and a plurality of second electrode fingers, in which an acoustic reflection portion is located at a position at which the support overlaps the IDT electrode in plan view in a direction in which the support and the piezoelectric film are laminated together, one ends of the plurality of first electrode fingers of the IDT electrode are connected to the first busbar, one ends of the plurality of second electrode fingers are connected to the second busbar, and the plurality of first electrode fingers and the plurality of second electrode fingers are interdigitated with each other, when a thickness of the piezoelectric film is d and a center-to-center distance between the first and second electrode fingers adjacent to each other is p, d/p is about 0.5 or less, when a direction in which the first electrode fingers and the second electrode fingers extend is an electrode finger extension direction and a direction orthogonal to the electrode finger extension direction is an electrode finger orthogonal direction, a region in which the first and second electrode fingers adjacent to each other overlap each other in the electrode finger orthogonal direction is an overlap region, and the overlap region includes a middle region and first and second edge regions on both sides of the middle region in the electrode finger extension direction, a region located between the first edge region and the first busbar is a first gap region, and a region located between the second edge region and the second busbar is a second gap region, the acoustic wave device further including a first mass-addition film provided over the first edge region and the first gap region, and a second mass-addition film provided over the second edge region and the second gap region, in which, when dimensions of the first mass-addition film and the second mass-addition film in the electrode finger extension direction are lengths of the first mass-addition film and the second mass-addition film, at least one of a pair of the length of the first mass-addition film in the first gap region and the length of the second mass-addition film in the second gap region and a pair of the length of the first mass-addition film in the first edge region and the length of the second mass-addition film in the second edge region differs from each other.

According to example embodiments of the present invention, it is possible to provide acoustic wave devices that each can reduce or prevent an unnecessary wave at frequencies close to and lower than the resonant frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic plan view of an acoustic wave device according to a first comparative example.

FIG. 4 is a diagram illustrating admittance frequency characteristics in the first example embodiment of the present invention and the first comparative example in which a distance L1 is about 100 nm.

FIG. 5 is a diagram illustrating admittance frequency characteristics in the first example embodiment of the present invention and the first comparative example in which the distance L1 is about 200 nm.

FIG. 6 is a diagram illustrating admittance frequency characteristics in the first example embodiment of the present invention and the first comparative example in which the distance L1 is about 300 nm.

FIG. 7 is a schematic plan view of an acoustic wave device according to a first modification of the first example embodiment of the present invention.

FIG. 8 is a schematic plan view of an acoustic wave device according to a second modification of the first example embodiment of the present invention.

FIG. 9 is a schematic plan view of an acoustic wave device according to a third modification of the first example embodiment of the present invention.

FIG. 10 is a schematic plan view of an acoustic wave device according to a second example embodiment of the present invention.

FIG. 11 is a schematic plan view of an acoustic wave device according to a third example embodiment of the present invention.

FIG. 12 is a schematic plan view of an acoustic wave device according to a second comparative example.

FIG. 13 is a diagram illustrating admittance frequency characteristics in the third example embodiment of the present invention and the second comparative example in which a distance L2 is about 100 nm.

FIG. 14 is a diagram illustrating admittance frequency characteristics in the third example embodiment of the present invention and the second comparative example in which the distance L2 is about 200 nm.

FIG. 15 is a diagram illustrating admittance frequency characteristics in the third example embodiment of the present invention and the second comparative example in which the distance L2 is about 300 nm.

FIG. 16 is a schematic plan view of an acoustic wave device according to a fourth example embodiment of the present invention.

FIG. 17 is a schematic plan view of an acoustic wave device according to a fifth example embodiment of the present invention.

FIG. 18 is a schematic plan view of an acoustic wave device according to a sixth example embodiment of the present invention.

FIG. 19A is a schematic perspective view illustrating the appearance of the acoustic wave device that uses a bulk wave in a thickness-shear mode, and FIG. 19B is a plan view illustrating an electrode structure on a piezoelectric layer.

FIG. 20 is a cross-sectional view taken along line A-A in FIG. 19A.

FIG. 21A is a schematic elevational cross-sectional view for describing a Lamb wave propagating through a piezoelectric film of the acoustic wave device, and FIG. 21B is a schematic elevational cross-sectional view for describing a bulk wave in the thickness-shear mode propagating through the piezoelectric film in the acoustic wave device.

FIG. 22 is a diagram illustrating an amplitude direction of a bulk wave in the thickness-shear mode.

FIG. 23 is a diagram illustrating resonance characteristics of the acoustic wave device that uses a bulk wave in the thickness-shear mode.

FIG. 24 is a diagram illustrating the relationship between d/p and a fractional bandwidth as a resonator when the center-to-center distance between adjacent electrodes is p and the thickness of the piezoelectric layer is d.

FIG. 25 is a plan view of the acoustic wave device that uses a bulk wave in the thickness-shear mode.

FIG. 26 is a diagram illustrating the resonance characteristics of an acoustic wave device according to a reference example in which spurious appears.

FIG. 27 is a diagram illustrating the relationship between the fractional bandwidth and the phase rotation amount of the impedance of spurious normalized by 180 degrees as the level of the spurious.

FIG. 28 is a diagram illustrating the relationship between d/2p and a metallization ratio (MR).

FIG. 29 is a diagram illustrating a map of the fractional bandwidth with respect to Euler angles (0°, θ, ψ) of LiNbO₃ when d/p is infinitely brought close to 0.

FIG. 30 is an elevational cross-sectional view of the acoustic wave device including an acoustic multilayer film.

### DETAILED DESCRIPTION OF THE EXAMPLE EMBODIMENTS

The present invention will be clarified below by specific example embodiments being described with reference to the drawings.

It should be noted that example embodiments described in this specification are exemplary, and partial substitution or combination of components between different example embodiments is possible.

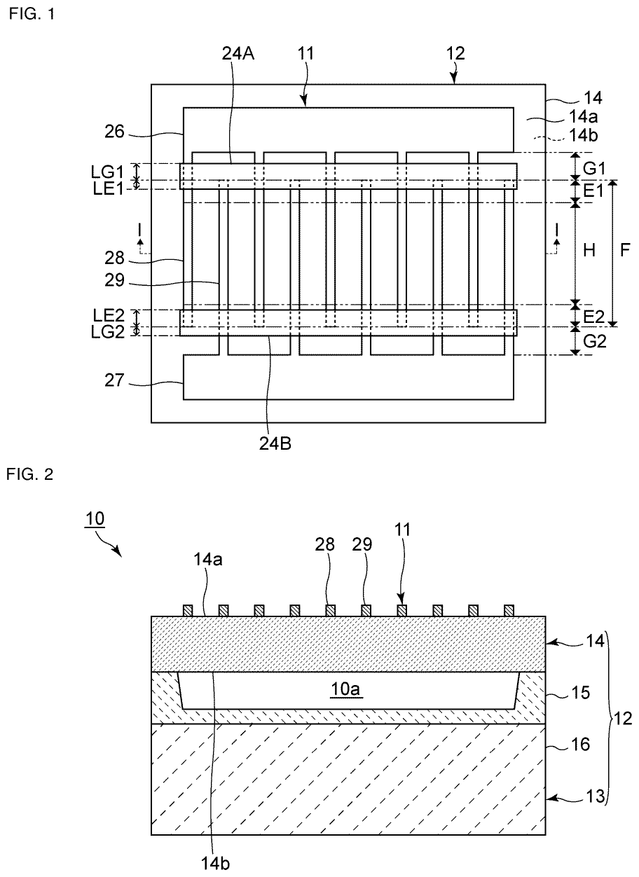

FIG. 1 is a schematic plan view of an acoustic wave device according to a first example embodiment of the present invention. FIG. 2 is a schematic cross-sectional view taken along line I-I in FIG. 1.

As illustrated in FIG. 1, an acoustic wave device 10 includes a piezoelectric substrate 12 and an IDT electrode 11. The piezoelectric substrate 12 is a substrate with piezoelectricity. As illustrated in FIG. 2, the piezoelectric substrate 12 includes a support 13 and a piezoelectric layer 14 that serves as a piezoelectric film. The piezoelectric layer 14 is a layer that includes a piezoelectric body. On the other hand, a piezoelectric film in this specification refers to a film with piezoelectricity and does not necessarily refer to a film that includes a piezoelectric body. However, in the present example embodiment, the piezoelectric film is the piezoelectric layer 14 including a single layer and is a film that includes a piezoelectric body. It should be noted that, in example embodiments of the present invention, the piezoelectric film may be a laminated film including the piezoelectric layer 14. In the present example embodiment, the support 13 includes a support substrate 16 and an insulation layer 15. The insulation layer 15 is provided on the support substrate 16. The piezoelectric layer 14 is provided on the insulation layer 15. However, the support 13 may include only the support substrate 16.

The piezoelectric layer 14 includes a first main surface 14a and a second main surface 14b. The first main surface 14a and the second main surface 14b face away from each other. The second main surface 14b is located closer to the support 13 than is the first main surface 14a.

The material of the t support substrate 16 may be a semiconductor, such as silicon, or a ceramic, such as aluminum oxide. The material of the insulation layer 15 may be an appropriate dielectric, such as silicon oxide or tantalum oxide. The piezoelectric layer 14 may be made of lithium niobate, such as LiNbO₃, or lithium tantalate, such as LiTaO₃. It should be noted that the piezoelectric layer 14 is made of lithium niobate in the present example embodiment. In this specification, when a certain component is made of a certain material, a small amount of impurities that do not significantly degrade electrical characteristics of the acoustic wave device may be included.

As illustrated in FIG. 2, a recesses portion is provided in the insulation layer 15. A piezoelectric layer 14 that serves as a piezoelectric film is provided on the insulation layer 15 so as to block the recessed portion. As a result, a hollow portion is provided. This hollow portion is a cavity portion 10a. In the present example embodiment, the support 13 and the piezoelectric film are disposed such that a portion of the support 13 and a portion of the piezoelectric film face each other with the cavity portion 10a therebetween. However, the recessed portion of the support 13 may also be provided over the insulation layer 15 and the support substrate 16. Alternatively, the recessed portion provided only in the support substrate 16 may also be blocked by the insulation layer 15. The recessed portion may also be provided in, for example, the piezoelectric layer 14. It should be noted that the cavity portion 10a may be a through-hole provided in the support 13.

The IDT electrode 11 is provided on the first main surface 14a of the piezoelectric layer 14. The acoustic wave device 10 according to the present example embodiment is an acoustic wave resonator capable of using a bulk wave in a thickness-shear mode. However, an acoustic wave device according to an example embodiment of the present invention may also be a multiplexer or a filter device that includes a plurality of acoustic wave resonators.

In plan view, at least a portion of the IDT electrode 11 overlaps the cavity portion 10a of the support 13. Plan view in this specification refers to view in a direction in which the support 13 and the piezoelectric film are laminated together from the top in FIG. 2. It should be noted that the top in FIG. 2 is closer to the piezoelectric layer 14 than to the support substrate 16. In addition, it is assumed that plan view in this specification is the same as view in a main surface facing direction. The main surface facing direction refers to a direction in which the first main surface 14a and the second main surface 14b of the piezoelectric layer 14 face away from each other. More specifically, the main surface facing direction is a direction normal to, for example, the first main surface 14a.

As illustrated in FIG. 1, the IDT electrode 11 includes a pair of busbars and a plurality of electrode fingers. Specifically, the pair of busbars are a first busbar 26 and a second busbar 27. The first busbar 26 and the second busbar 27 face each other. Specifically, the plurality of electrode fingers are a plurality of first electrode fingers 28 and a plurality of second electrode fingers 29. One ends of the plurality of first electrode fingers 28 are connected to the first busbar 26. One ends of the plurality of second electrode fingers 29 are connected to the second busbar 27. The plurality of first electrode fingers 28 and the plurality of second electrode fingers 29 are interdigitated with each other. The IDT electrode 11 may include a single metal film or a plurality of laminated metal films.

In the following description, the first electrode fingers 28 and the second electrode fingers 29 may be collectively referred to as the electrode fingers. The direction in which the plurality of electrode fingers extend is referred to as an electrode finger extension direction, and the direction orthogonal to the electrode finger extension direction is referred to as an electrode finger orthogonal direction. It should be noted that, when the direction in which adjacent electrode fingers face each other is referred to as an electrode finger facing direction, the electrode finger orthogonal direction and the electrode finger facing direction are parallel to each other.

Returning to FIG. 1, a region in which the first and second electrode fingers 28 and 29 adjacent to each other overlap each other in the electrode finger orthogonal direction is an overlap region F. The overlap region F includes a middle region H and a pair of edge regions. Specifically, the pair of edge regions include a first edge region E1 and a second edge region E2. The first edge region E1 and the second edge region E2 are disposed on both sides of the middle region H in the electrode finger extension direction. The first edge region E1 is located closer to the first busbar 26. The second edge region E2 is located closer to the second busbar 27.

A region located between the overlap region F and the pair of busbars is a pair of gap regions. Specifically, the pair of gap regions are a first gap region G1 and a second gap region G2. The first gap region G1 is located between the first busbar 26 and the first edge region E1. The second gap region G2 is located between the second busbar 27 and the second edge region E2.

The acoustic wave device 10 is an acoustic wave resonator capable of using a bulk wave in the thickness-shear mode. More specifically, in the acoustic wave device 10, when the thickness of the piezoelectric film is d and the center-to-center distance between the first and second electrode fingers 28 and 29 adjacent to each other is p, d/p is about 0.5 or less, for example. As a result, a bulk wave in the thickness-shear mode is preferably excited. It should be noted that the thickness d is the thickness of the piezoelectric layer 14 in the present example embodiment.

The region, disposed between middle positions of the first and second electrode fingers 28 and 29 adjacent to each other in the electrode finger orthogonal direction, in which the first and second electrode fingers 28 and 29 adjacent to each other overlap each other in the electrode finger orthogonal direction is an excitation region. That is, the overlap region F includes a plurality of excitation regions. A bulk wave in the thickness-shear mode is excited in each of the excitation regions. It should be noted that the overlap region F, the excitation regions, and the pair of gap regions are regions of the piezoelectric layer 14 that are defined in accordance with the structure of the IDT electrode 11.

The cavity portion 10a of the support 13 illustrated in FIG. 2 is an acoustic reflection portion according to an example embodiment of the present invention. The acoustic reflection portion enables the energy of an acoustic wave to be effectively confined in a portion closer to the piezoelectric layer 14. It should be noted that an acoustic multilayer film, which will be described later, may also be provided as the acoustic reflection portion. For example, the acoustic reflection film may also be provided on the surface of the support.

As illustrated in FIG. 1, in the present example embodiment, the acoustic wave device 10 includes one first mass-addition film 24A and one second mass-addition film 24B. The first mass-addition film 24A is provided over the first edge region E1 and the first gap region G1. The second mass-addition film 24B is provided over the second edge region E2 and the second gap region G2. The first mass-addition film 24A and the second mass-addition film 24B have a belt shape.

The first mass-addition film 24A is provided on the first main surface 14a of the piezoelectric layer 14 so as to cover the plurality of electrode fingers. When the region between the first electrode finger 28 and the second electrode finger 29 is an inter-electrode-finger region, the first mass-addition film 24A is also provided in a portion of the first main surface 14a located in the inter-electrode-finger region. That is, the first mass-addition film 24A is continuously provided so as to overlap the plurality of first electrode fingers 28, the plurality of second electrode fingers 29, and the inter-electrode-finger regions in plan view. The second mass-addition film 24B is also continuously provided so as to overlap the plurality of first electrode fingers 28, the plurality of second electrode fingers 29, and the inter-electrode-finger regions in plan view.

In the following description, it is assumed that the dimensions of the first mass-addition film 24A and the second mass-addition film 24B in the electrode finger extension direction are the lengths of the first mass-addition film 24A and the second mass-addition film 24B. It is assumed that the length of the first mass-addition film 24A in the first gap region G1 is LG1, and the length of the first mass-addition film 24A in the first edge region E1 is LE1. It is assumed that the length of the second mass-addition film 24B in the second gap region G2 is LG2, and the length of the second mass-addition film 24B in the second edge region E2 is LE2. It is assumed that the sum of the lengths of the first mass-addition film 24A in the first edge region E1 and first gap region G1 is LT1, and the sum of the lengths of the second mass-addition film 24B in the second edge region E2 and the second gap region G2 is LT2.

In the present example embodiment, LT1=LT2 is satisfied. That is, LG1+LE1=LG2+LE2 is satisfied. On the other hand, LG1>LG2 and LE1<LE2 are satisfied.

One of the unique features of the present example embodiment is LG1/LG2 and LE1 #LE2. That is, in the present example embodiment, the length of the first mass-addition film 24A in the first gap region G1 and the length of the second mass-addition film 24B in the second gap region G2 differ from each other. The length of the first mass-addition film 24A in the first edge region E1 and the length of the second mass-addition film 24B in the second edge region E2 differ from each other. As a result, an unnecessary wave can be suppressed at frequencies close to and lower than the resonant frequency. This will be described below by comparison between the present example embodiment and the first comparative example.

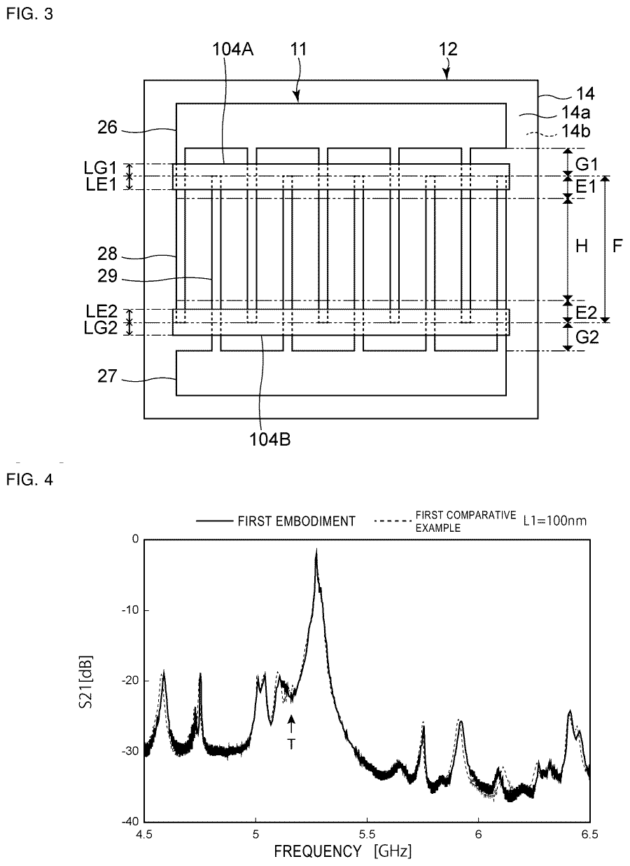

As illustrated in FIG. 3, in the first comparative example, a first mass-addition film 104A is provided over the first edge region E1 and the first gap region G1. A second mass-addition film 104B is provided over the second edge region E2 and the second gap region G2. The first comparative example differs from the first example embodiment in that LG1=LG2 and LE1=LE2 are satisfied.

It should be noted that, the sum LT1 of the lengths of the first mass-addition film in the first edge region E1 and the first gap region G1 is the same between the first example embodiment and the first comparative example. The sum LT2 of the lengths of the second mass-addition film in the second edge region E2 and the second gap region G2 is also the same between the first example embodiment and the first comparative example. In the structure in the first example embodiment, both the first mass-addition film 24A and the second mass-addition film 24B are provided closer to the first busbar 26 than in the first comparative example.

Here, it is assumed that the positions of the first mass-addition film 104A and the second mass-addition film 104B in the first comparative example are the reference positions. It is assumed that the distance in the electrode finger extension direction from the reference positions of the first mass-addition film 24A and the second mass-addition film 24B in the first example embodiment is the distance L1. The plurality of acoustic wave devices 10 in which the distance L1 differed from each other were prepared as the acoustic wave devices 10 having the structure in the first example embodiment. Specifically, in the plurality of acoustic wave devices 10 having the structure in the first example embodiment, the distance L1 is about 100 nm, about 200 nm, or about 300 nm, for example. The admittance frequency characteristics were compared between the acoustic wave devices according to the first example embodiment and the first comparative example.

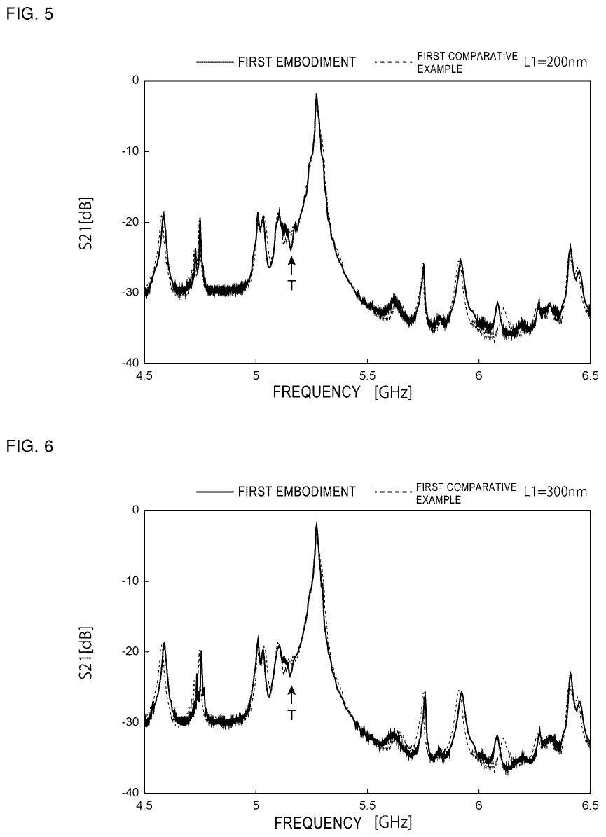

FIG. 4 is a diagram illustrating admittance frequency characteristics in the first example embodiment and the first comparative example in which the distance L1 is about 100 nm, for example. FIG. 5 is a diagram illustrating admittance frequency characteristics in the first example embodiment and the first comparative example in which the distance L1 is about 200 nm, for example. FIG. 6 is a diagram illustrating admittance frequency characteristics in the first example embodiment and the first comparative example in which the distance L1 is about 300 nm, for example.

As indicated by arrow T in FIGS. 4 to 6, it can be seen that an unnecessary wave at frequencies close to and lower than the resonant frequency suppressed in the first example embodiment. It can be seen that an unnecessary wave is further suppressed when the distance L1 is about 200 nm and about 300 nm, for example, as illustrated in FIGS. 5 and 6. In the following description, unless otherwise specified, an unnecessary wave is assumed to have frequencies lower than and close to the resonant frequency.

In the acoustic wave device 10 according to the first example embodiment, LG1 ¥ LG2 and LE1 #LE2 are satisfied. As a result, frequencies at which an unnecessary wave is generated can be distributed, and the overall intensity of an unnecessary wave can be reduced. As a result, an unnecessary wave can be suppressed.

In an example embodiment of the present invention, at least one of a pair of the length LG1 of the first mass-addition film 24A and the length LG2 of the second mass-addition film 24B and a pair of the length LE1 of the first mass-addition film 24A and the length LE2 of the second mass-addition film 24B only needs to differ from each other. That is, at least one of LG1 ¥ LG2 and LE1 #LE2 only needs to be satisfied. Also in this case, frequencies at which an unnecessary wave is generated can be distributed and an unnecessary wave can be suppressed.

In the first example embodiment, the sum of the length of the first mass-addition film 24A in the first edge region E1 and the length of the first mass-addition film 24A in the first gap region G1 and the sum of the length of the second mass-addition film 24B in the second edge region E2 and the length of the second mass-addition film 24B in the second gap region G2 are the same as each other. That is, LT1=LT2 is satisfied. However, the present invention is not limited to this example. First to third modifications of the first example embodiment in which LT1 ¥ LT2 is satisfied will be described below. Also in the first to third modifications, at least one of LG1/LG2 and LE1 ¥ LE2 is satisfied. As a result, an unnecessary wave can be suppressed as in the first example embodiment.

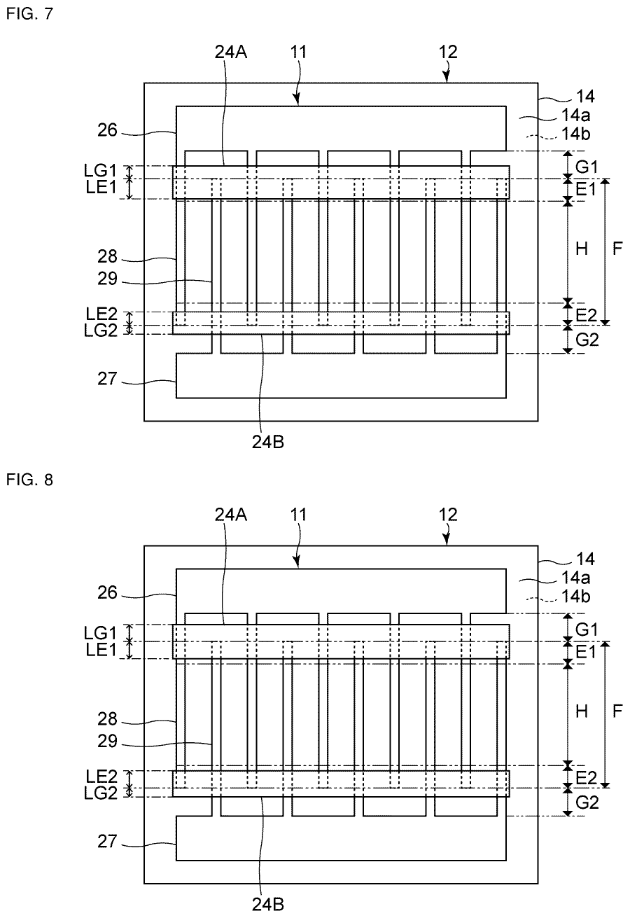

In the first modification illustrated in FIG. 7, LE1>LE2 and LG1>LG2 are satisfied. That is, the length of the first mass-addition film 24A in the first edge region E1 is greater than the length of the second mass-addition film 24B in the second edge region E2. The length of the first mass-addition film 24A in the first gap region G1 is greater than the length of the second mass-addition film 24B in the second gap region G2. Accordingly, the sum of the length of the first mass-addition film 24A in the first edge region E1 and the length of the first mass-addition film 24A in the first gap region G1 and the sum of the length of the second mass-addition film 24B in the second edge region E2 and the length of the second mass-addition film 24B in the second gap region G2 differ from each other.

In the second modification illustrated in FIG. 8, LE1=LE2 and LG1>LG2 are satisfied. That is, the length of the first mass-addition film 24A in the first edge region E1 and the length of the second mass-addition film 24B in the second edge region E2 are the same as each other. The length of the first mass-addition film 24A in the first gap region G1 is greater than the length of the second mass-addition film 24B in the second gap region G2.

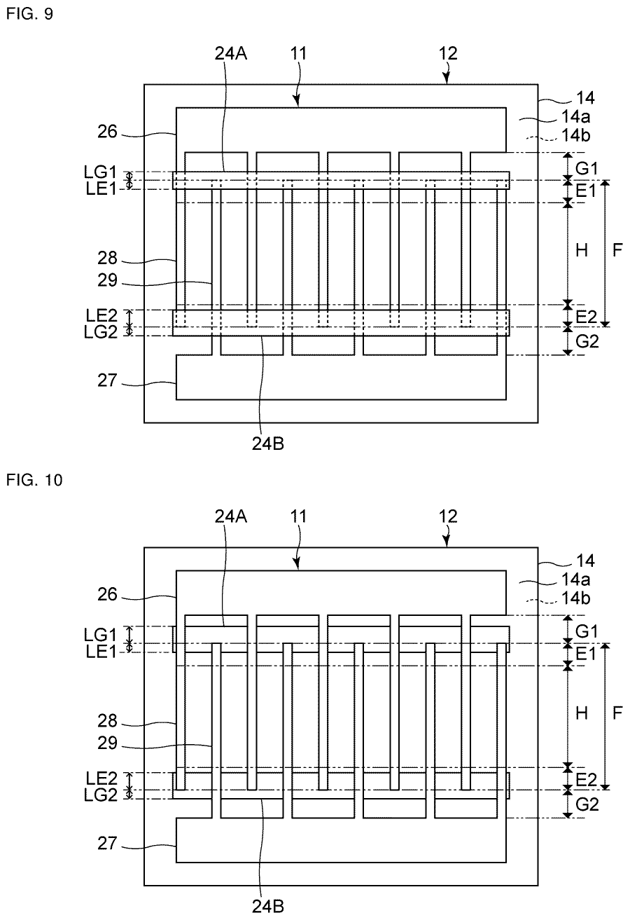

In the third modification illustrated in FIG. 9, LE1<LE2 and LG1=LG2 are satisfied. That is, the length of the first mass-addition film 24A in the first edge region E1 is smaller than the length of the second mass-addition film 24B in the second edge region E2. The length of the first mass-addition film 24A in the first gap region G1 is and the length of the second mass-addition film 24B in the second gap region G2 are the same as each other.

Returning to FIG. 1, the first mass-addition film 24A and the second mass-addition film 24B only need to overlap a plurality of electrode fingers in plan view and do not need to overlap all of the electrode fingers. However, the first mass-addition film 24A and the second mass-addition film 24B preferably overlap all of the electrode fingers in plan view. As a result, an unnecessary wave can be suppressed with greater certainty.

At least one of silicon oxide, tungsten oxide, niobium oxide, tantalum oxide, or hafnium oxide is preferably used as the materials of the first mass-addition film 24A and the second mass-addition film 24B. As a result, an unnecessary wave can be suppressed with greater certainty.

In the first example embodiment, in a portion in which the first mass-addition film 24A and the first electrode fingers 28 are laminated together, the piezoelectric layer 14, the first electrode fingers 28, and the first mass-addition film 24A are laminated together in this order. In a portion in which the second mass-addition film 24B and the first electrode fingers 28 are laminated together, the piezoelectric layer 14, the first electrode fingers 28, and the second mass-addition film 24B are laminated together in this order. The same applies to a portion in which the first mass-addition film 24A and the second electrode finger 29 are laminated together and a portion in which the second mass-addition film 24B and the second electrode finger 29 are laminated together. However, the order in which the first mass-addition film 24A, the second mass-addition film 24B, and the electrode fingers are laminated together is not limited to the order described above.

FIG. 10 is a schematic plan view of an acoustic wave device according to a second example embodiment.

The present example embodiment differs from the first example embodiment in that the first mass-addition film 24A and the second mass-addition film 24B are provided between the piezoelectric layer 14 and the IDT electrode 11. The acoustic wave device according to the present example embodiment has the same structure as the acoustic wave device 10 according to the first example embodiment with the exception of the point described above.

In a portion in which the first mass-addition film 24A and the first electrode fingers 28 are laminated together, the piezoelectric layer 14, the first mass-addition film 24A, and the first electrode finger 28 are laminated together in this order. In a portion in which the second mass-addition film 24B and the first electrode fingers 28 are laminated together, the piezoelectric layer 14, the second mass-addition film 24B, and the first electrode fingers 28 are laminated together in this order. The same applies to a portion in which the first mass-addition film 24A and the second electrode fingers 29 are laminated together and a portion in which the second mass-addition film 24B and the second electrode finger 29 are laminated together.

Also in the present example embodiment, at least one of LG1≠LG2 and LE1≠LE2 is satisfied as in the first example embodiment. Specifically, LG1≠LG2 and LE1≠LE2 are satisfied. As a result, an unnecessary wave can be suppressed.

In the first example embodiment and the second example embodiment, the first mass-addition film 24A and the second mass-addition film 24B are continuously provided so as to overlap the plurality of electrode fingers and the inter-electrode-finger regions in plan view. It should be noted that one first mass-addition film 24A and one second mass-addition film 24B do not need to overlap the plurality of electrode fingers in plan view. This example will be described as a third example embodiment.

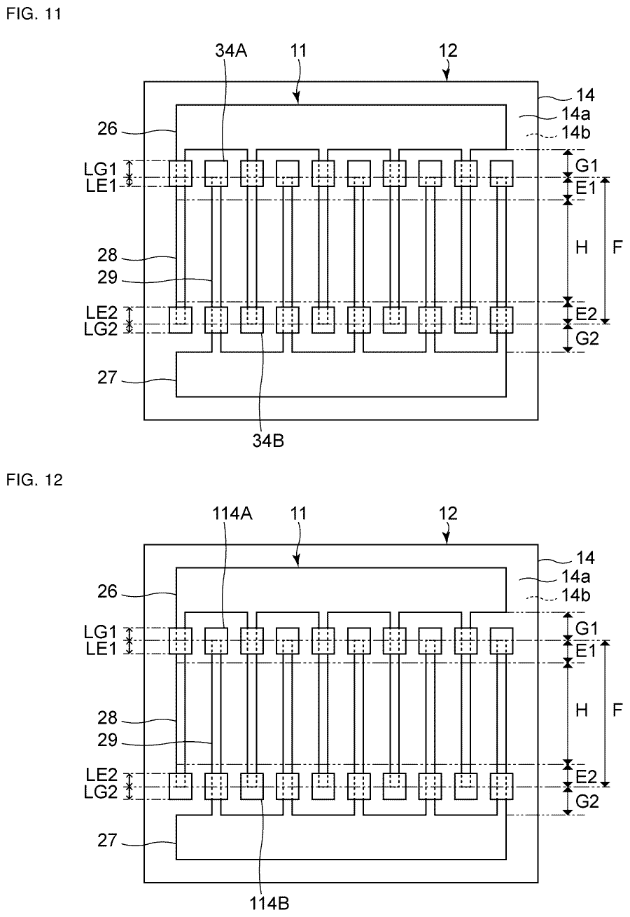

FIG. 11 is a schematic plan view of an acoustic wave device according to the third example embodiment.

The present example embodiment differs from the first example embodiment in that a plurality of first mass-addition films 34A are provided over the first edge region E1 and the first gap region G1. The present example embodiment differs from the first example embodiment also in that a plurality of second mass-addition films 34B are provided over the second edge region E2 and the first gap region G2. The acoustic wave device according to the present example embodiment has the same structure as the acoustic wave device 10 according to the first example embodiment with the exception of the point described above.

The plurality of first mass-addition films 34A are arranged in the electrode finger orthogonal direction. Each of the first mass-addition films 34A overlaps one first electrode finger 28 or one second electrode finger 29 in plan view. Specifically, each of the first mass-addition films 34A is provided over the first main surface 14a of the piezoelectric layer 14 and one electrode finger. Each of the first mass-addition films 34A does not extend over a plurality of electrode fingers.

The plurality of second mass-addition films 34B are arranged in the electrode finger orthogonal direction. Each of the second mass-addition films 34B overlaps one first electrode finger 28 or one second electrode finger 29 in plan view. Specifically, each of the second mass-addition films 34B is provided over the first main surface 14a of the piezoelectric layer 14 and one electrode finger. Each of the second mass-addition films 34B does not extend over a plurality of electrode fingers.

Also in the present example embodiment, at least one of LG1≠LG2 and LE1≠LE2 is satisfied as in the first example embodiment. Specifically, LG1≠LG2 and LE1≠LE2 are satisfied. As a result, an unnecessary wave can be suppressed. This will be described by comparison between the present example embodiment and the second comparative example.

As illustrated in FIG. 12, in the second comparative example, a plurality of first mass-addition films 114A are provided over the first edge region E1 and the first gap region G1. A plurality of second mass-addition films 114B are provided over the second edge region E2 and the second gap region G2. The second comparative example differs from the third example embodiment in that LG1=LG2 and LE1=LE2 are satisfied.

It should be noted that, the sum of the lengths of the first mass-addition films in the first edge region E1 and the first gap region G1 is the same between the third example embodiment and the second comparative example. The sum of the lengths of the second mass-addition films in the second edge region E2 and the second gap region G2 is also the same between the third example embodiment and the second comparative example. In the structure in the third example embodiment, both the first mass-addition films 34A and the second mass-addition films 34B are provided closer to the first busbar 26 than in the second comparative example.

Here, it is assumed that the positions of the first mass-addition films 114A and the second mass-addition films 114B in the second comparative example are the reference positions. It is assumed that the distance in the electrode finger extension direction from the reference positions of the first mass-addition films 34A and the second mass-addition films 34B in the third example embodiment is the distance L2. The plurality of acoustic wave devices in which the distance L2 differed from each other were prepared as the acoustic wave devices having the structure in the third example embodiment. Specifically, in the plurality of acoustic wave devices having the structure in the third example embodiment, the distance L2 is about 100 nm, about 200 nm, or about 300 nm, for example. The admittance frequency characteristics were compared between the acoustic wave devices according to the third example embodiment and the second comparative example.

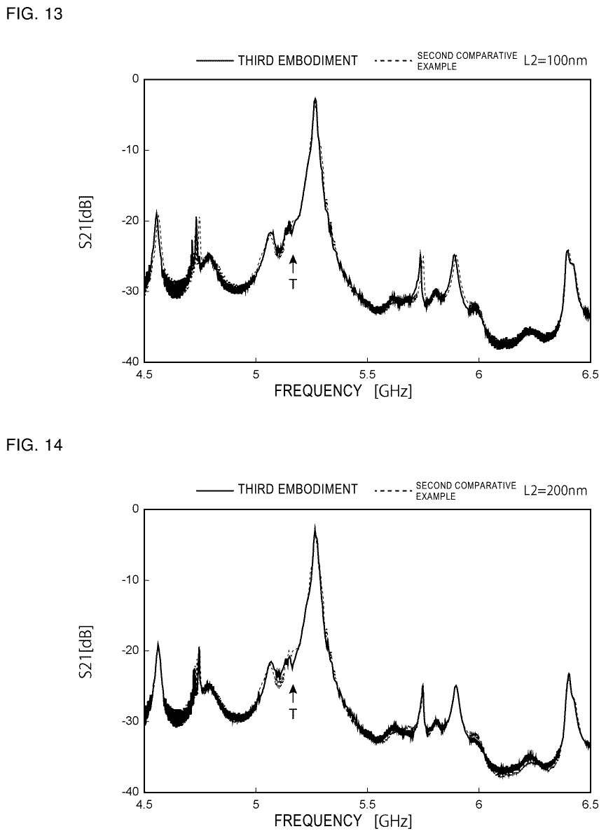

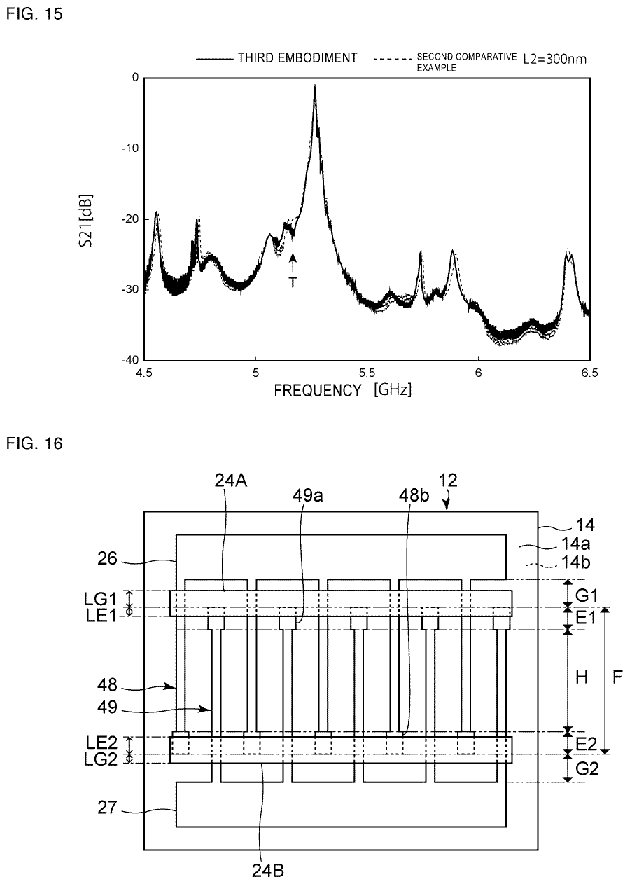

FIG. 13 is a diagram illustrating admittance frequency characteristics in the third example embodiment and the second comparative example in which the distance L2 is about 100 nm, for example. FIG. 14 is a diagram illustrating admittance frequency characteristics in the third example embodiment and the second comparative example in which the distance L2 is about 200 nm, for example. FIG. 15 is a diagram illustrating admittance frequency characteristics in the third example embodiment and the second comparative example in which the distance L2 is about 300 nm, for example.

As indicated by arrow T in FIGS. 13 to 15, it can be seen that an unnecessary wave at frequencies close to and lower than the resonant frequency is suppressed in the third example embodiment. It can be seen that an unnecessary wave is further suppressed when the distance L2 is about 200 nm and about 300 nm, as illustrated in FIGS. 14 and 15.

In the third example embodiment, in a portion in which the first mass-addition films 34A and the electrode fingers are laminated together, the piezoelectric layer 14, the electrode fingers, and the first mass-addition films 34A are laminated together in this order. In a portion in which the second mass-addition films 34B and the electrode fingers are laminated together, the piezoelectric layer 14, the electrode fingers, and the second mass-addition films 34B are laminated together in this order.

However, as in the second example embodiment, in a portion in which the first mass-addition films 34A and the electrode fingers are laminated together, the piezoelectric layer 14, the first mass-addition films 34A, and the electrode fingers may be laminated together in this order. In a portion in which the second mass-addition films 34B and the electrode fingers are laminated together, the piezoelectric layer 14, the second mass-addition films 34B, and the electrode fingers may be laminated together in this order.

Each of the first mass-addition films 34A is in contact with only the first electrode finger 28 or only the second electrode finger 29 of the first electrode fingers 28 and the second electrode fingers 29. In this case, the first mass-addition films 34A may also be made of a metal. Similarly, the second mass-addition films 34B may also be made of a metal.

FIG. 16 is a schematic plan view of an acoustic wave device according to a fourth example embodiment.

The present example embodiment differs from the first example embodiment in the structures of a plurality of first electrode fingers 48 and the plurality of second electrode fingers 49. The acoustic wave device according to the present example embodiment has the same structure as the acoustic wave device 10 according to the first example embodiment with the exception of the point described above.

Each of the plurality of first electrode fingers 48 includes a widened portion 48b. The width of the electrode finger in the widened portion is greater than the width of the electrode finger in the middle region H. It should be noted that the width of the electrode finger is a dimension in the electrode finger orthogonal direction. The widened portion 48b of the first electrode finger 48 is specifically located in the second edge region E2.

Each of the plurality of second electrode fingers 49 has a widened portion 49a. The widened portion 49a of the second electrode finger 49 is specifically located in the first edge region E1.

Also in the present example embodiment, at least one of LG1≠LG2 and LE1≠LE2 is satisfied as in the first example embodiment. Specifically, LG1≠LG2 and LE1≠LE2 are satisfied. In addition, each of the electrode fingers has the widened portion as described above. As a result, frequencies at which an unnecessary wave is generated can be effectively distributed. As a result, an unnecessary wave can be effectively suppressed.

The width of the first electrode finger 48 in the first edge region E1 is the same as the width of the electrode finger in the middle region H. However, each of the plurality of first electrode fingers 48 may also have a widened portion located in the first edge region E1.

The width of the second electrode finger 49 in the second edge region E2 is the same as the width of the electrode finger in the middle region H. However, each of the plurality of second electrode fingers 49 may also have a widened portion located in the second edge region E2.

Even when the first electrode finger 48 and the second electrode finger 49 each have a widened portion, the plurality of first mass-addition films 34A and the plurality of second mass-addition films 34B may be provided, as in the third example embodiment illustrated in FIG. 11.

In the first to fourth example embodiments, the first mass-addition film and the second mass-addition film are provided directly on the plurality of electrode fingers and the piezoelectric layer 14. However, the first mass-addition film and the second mass-addition film may be provided indirectly on the plurality of electrode fingers and the piezoelectric layer 14 via a dielectric film. This example will be described as a fifth example embodiment.

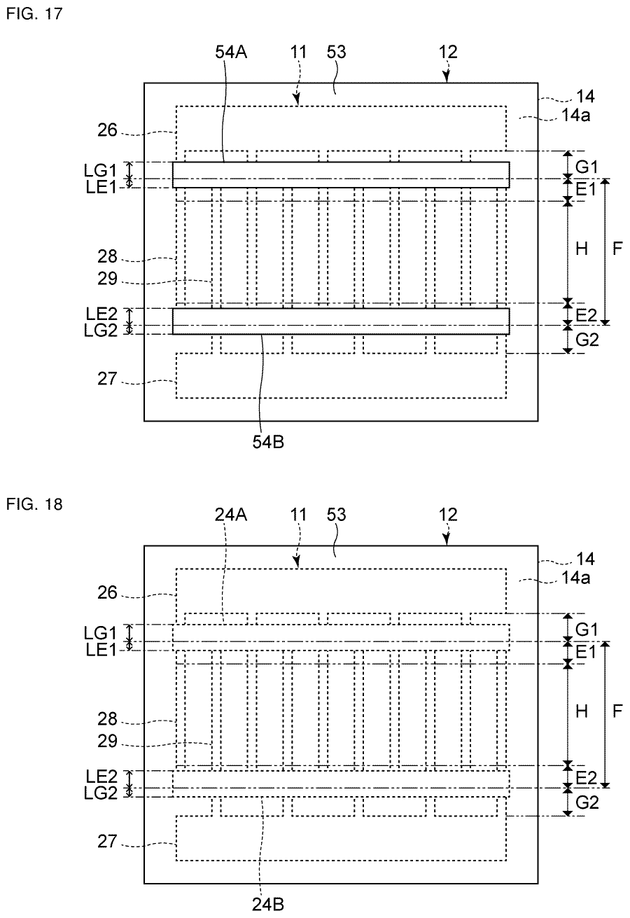

FIG. 17 is a schematic plan view of an acoustic wave device according to the fifth example embodiment.

In addition, the present example embodiment differs from the first example embodiment in that a dielectric film 53 is provided on the first main surface 14a of the piezoelectric layer 14 so as to cover the IDT electrode 11. The present example embodiment differs from the first example embodiment also in that a first mass-addition film 54A and a second mass-addition film 54B are made of metals. The acoustic wave device according to the present example embodiment has the same structure as the acoustic wave device 10 according to the first example embodiment with the exception of the point described above.

The first mass-addition film 54A and the second mass-addition film 54B are provided on the dielectric film 53. The first mass-addition film 54A is provided over the first edge region E1 and the first gap region G1 as in the first example embodiment. The first mass-addition film 54A is continuously provided so as to overlap the plurality of first electrode fingers 28, the plurality of second electrode fingers 29, and the inter-electrode-finger regions in plan view.

As in the first example embodiment, the second mass-addition film 54B is provided over the second edge region E2 and the second gap region G2. The second mass-addition film 54B is continuously provided so as to overlap the plurality of first electrode fingers 28, the plurality of second electrode fingers 29, and the inter-electrode-finger regions in plan view.

In the present example embodiment, the dielectric film 53 is made of silicon oxide. It should be noted that the material of the dielectric film 53 is not limited to the one described above. The material of the dielectric film 53 may be, for example, silicon nitride or silicon oxynitride.

The first mass-addition film 54A and the second mass-addition film 54B are made of appropriate metals. However, the first mass-addition film 54A and the second mass-addition film 54B may also be made of appropriate dielectrics. In this case, at least one of silicon oxide, tungsten oxide, niobium oxide, tantalum oxide, or hafnium oxide is preferably used as the materials of the first mass-addition film 54A and the second mass-addition film 54B.

Also in the present example embodiment, at least one of LG1≠LG2 and LE1≠LE2 is satisfied as in the first example embodiment. Specifically, LG1≠LG2 and LE1≠LE2 are satisfied. As a result, an unnecessary wave can be suppressed.

In addition, the IDT electrode 11 is protected by the dielectric film 53. As a result, the IDT electrode 11 is less likely to be broken. In addition, the frequency of the acoustic wave device can be easily adjusted by the thickness of the dielectric film 53 being adjusted.

In the present example embodiment, the piezoelectric layer 14, the dielectric film 53, and the first mass-addition film 54A are laminated together r in this order. Similarly, the piezoelectric layer 14, the dielectric film 53, and the second mass-addition film 54B are laminated together in this order. However, when, for example, the first mass-addition film 54A is made of a dielectric, the order in which the piezoelectric layer 14, the dielectric film 53, and the first mass-addition film 54A are laminated together is not limited to the order described above. Similarly, the order in which the piezoelectric layer 14, the dielectric film 53, and the second mass-addition film 54B are laminated together is not limited to the order described above.

FIG. 18 is a schematic plan view of an acoustic wave device according to a sixth example embodiment.

The present example embodiment differs from the fifth example embodiment in that the first mass-addition film 24A and the second mass-addition film 24B are made of dielectrics. The present example embodiment differs from the fifth example embodiment also in that the dielectric film 53 is provided on the first main surface 14a of the piezoelectric layer 14 so as to cover the IDT electrode 11, the first mass-addition film 24A, and the second mass-addition film 24B. The acoustic wave device according to the present example embodiment has the same structure as the acoustic wave device according to the fifth example embodiment with the exception of the point described above.

The piezoelectric layer 14, the first mass-addition film 24A, and the dielectric film 53 are laminated together in this order. Similarly, the piezoelectric layer 14, the second mass-addition film 24B, and the dielectric film 53 are laminated together in this order.

Also in the present example embodiment, at least one of LG1≠LG2 and LE1≠LE2 is satisfied as in the fifth example embodiment. Specifically, LG1≠LG2 and LE1≠LE2 are satisfied. As a result, an unnecessary wave can be suppressed.

The thickness-shear mode will be described in detail below. It should be noted that the electrode of the IDT electrode, which will be described later, corresponds to the electrode finger described herein. The support in the following examples corresponds to the support substrate described herein.

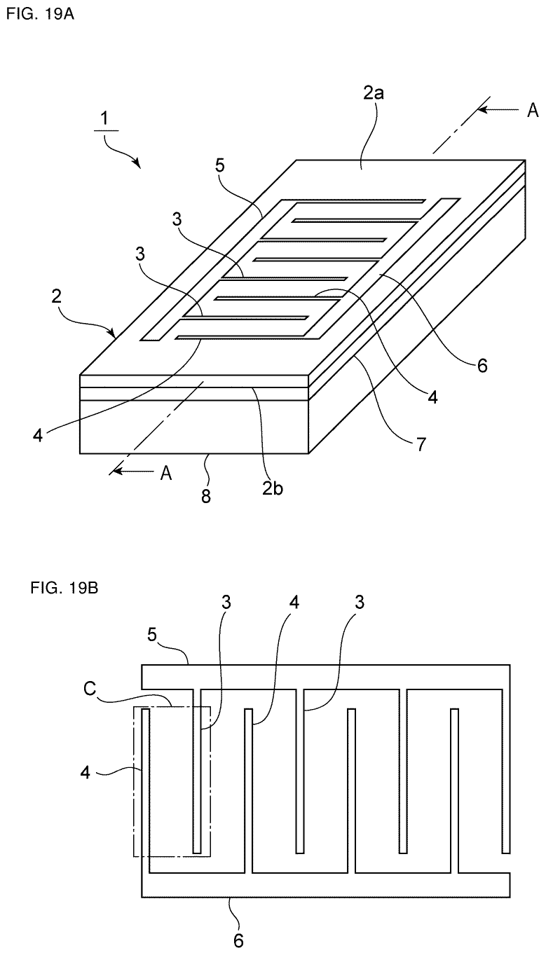

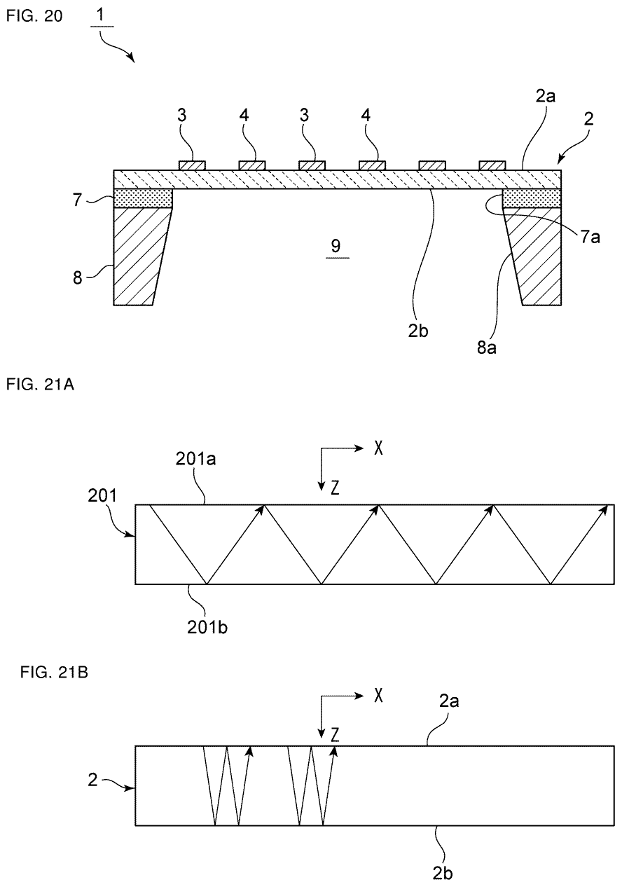

FIG. 19A is a schematic perspective view illustrating the appearance of the acoustic wave device that uses a bulk wave in the thickness-shear mode, FIG. 19B is a plan view illustrating the electrode structure on the piezoelectric layer, and FIG. 20 is a cross-sectional view taken along line A-A in FIG. 19A.

The acoustic wave device 1 includes a piezoelectric layer 2 made of LiNbO₃. The piezoelectric layer 2 may be made of LiTaO₃. The cut angle of LiNbO₃ and LiTaO₃ is Z-cut but may also be a rotated Y-cut or an X-cut. The thickness of the piezoelectric layer 2 is not particularly limited but is preferably about 40 nm or more and about 1000 nm or less to effectively excite the thickness-shear mode and more preferably about 50 nm or more and about 1000 nm or less, for example. The piezoelectric layer 2 has first and second main surfaces 2a and 2b that face away from each other. An electrode 3 and an electrode 4 are provided on the first main surface 2a. Here, the electrode 3 is an example of the first electrode, and the electrode 4 is an example of the second electrode. In FIGS. 19A and 19B, the plurality of electrodes 3 are the plurality of first electrode fingers that are connected to a first busbar 5. The plurality of electrodes 4 are the plurality of second electrode fingers that are connected to a second busbar 6. The plurality of electrodes 3 and the plurality of electrodes 4 are interdigitated with each other. The electrode 3 and the electrode 4 are rectangular and have a length direction. The electrode 3 and the electrode 4 adjacent thereto face each other in the direction orthogonal to the length direction. The length direction of the electrodes 3 and 4 and the direction orthogonal to the length direction of the electrodes 3 and 4 intersect the thickness direction of the piezoelectric layer 2. Accordingly, it can be said that the electrode 3 and the electrode 4 adjacent thereto face each other in a direction intersecting the thickness direction of the piezoelectric layer 2. In addition, the length direction of the electrodes 3 and 4 may be replaced with the direction orthogonal to the length direction of the electrodes 3 and 4 illustrated in FIGS. 19A and 19B. That is, in FIGS. 19A and 19B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 19A and 19B. In addition, a plurality of pairs of adjacent electrodes 3 and 4 connected to one potential and the other potential, respectively, are provided in a direction orthogonal to the length direction of the electrodes 3 and 4. Here, the adjacent electrodes 3 and 4 refer to the electrodes 3 and 4 disposed with a gap therebetween instead of the electrodes 3 and 4 in direct contact with each other. In the adjacent electrodes 3 and 4, electrodes connected to a hot electrode or a ground electrode including other electrodes 3 and 4 are not disposed between the electrodes 3 and 4. The number of pairs does not need to be an integer and may be 1.5 pairs or 2.5 pairs, for example. The center-to-center distance (that is, the pitch) between the electrodes 3 and 4 is preferably about 1 μm or more and about 10 μm or less, for example. In addition, the widths of the electrodes 3 and 4, that is, the dimensions of the electrodes 3 and 4 in the facing direction are preferably about 50 nm or more and about 1000 nm or less and more preferably about 150 nm or more and about 1000 nm or less, for example. It should be noted that the center-to-center distance between the electrodes 3 and 4 is the distance between the middle of the dimension (width dimension) of the electrode 3 in the direction orthogonal to the length direction of the electrode 3 and the middle of the dimension (width dimension) of the electrode 4 in the direction orthogonal to the length direction of the electrode 4.

In addition, since the Z-cut piezoelectric layer is used in the acoustic wave device 1, the direction orthogonal to the length direction of the electrodes 3 and 4 is orthogonal to the polarization direction of the piezoelectric layer 2. The same does not apply when a piezoelectric body with another cut angle is used as the piezoelectric layer 2. Here, “orthogonal” is not limited to “strictly orthogonal” and may be “substantially orthogonal” (when the angle formed by the polarization direction and the direction orthogonal to the length direction of the electrodes 3 and 4 is, for example, about) 90°+10°.

A support 8 is laminated on the second main surface 2b of the piezoelectric layer 2 with an insulation layer r 7 therebetween. The insulation layer 7 and the support 8 are frame-shaped and have through-holes 7a and 8a as illustrated in FIG. 20. As a result, a cavity portion 9 is provided. The cavity portion 9 is provided not to interfere with the vibration of the excitation region C of the piezoelectric layer 2. Accordingly, the support 8 is laminated on the second main surface 2b with the insulation layer 7 therebetween at a position that does not overlap a portion in which at least one pair of electrodes 3 and 4 is provided. It should be noted that the insulation layer 7 does not need to be provided. Accordingly, the support 8 can be laminated directly or indirectly on the second main surface 2b of the piezoelectric layer 2.

The insulation layer 7 is made of silicon oxide. However, appropriate insulation materials other than silicon oxide, such as silicon oxynitride or alumina, can also be used. The support 8 is made of Si. The plane direction of the surface of Si closer to the piezoelectric layer 2 may be (100) or (110) or may be (111). The resistance of Si of the support 8 preferably has a high resistivity of about 4 kΩcm or more, for example. However, the support 8 can be made of an appropriate insulation material or semiconductor material.

The material of the support 8 can be a piezoelectric body such as aluminum oxide, lithium tantalate, lithium niobate, or quartz, a ceramic such as alumina, magnesia, sapphire, silicon nitride, aluminum nitride, silicon carbide, zirconia, cordierite, mullite, steatite, or forsterite, a dielectric such as diamond or glass, or a semiconductor such as gallium nitride.

The plurality of electrodes 3 and 4 and the first and second busbars 5 and 6 are made of an appropriate metal or alloy, such as Al or Al—Cu alloy. In the present example embodiment, the electrodes 3 and 4 and the first and second busbars 5 and 6 have a structure in which an Al film is laminated on a Ti film. It should be noted that a close contact layer other than a Ti film may be used.

An AC voltage is applied between the plurality of electrodes 3 and the plurality of electrodes 4 to perform driving. More specifically, an AC voltage is applied between the first busbar 5 and the second busbar 6. This can obtain resonance characteristics that uses a bulk wave in the thickness-shear mode excited by the piezoelectric layer 2. In addition, in the acoustic wave device 1, when the thickness of the piezoelectric layer 2 is d and the center-to-center distance between any adjacent electrodes 3 and 4 of the plurality of pairs of electrodes 3 and 4 is p, d/p is set to be about 0.5 or less, for example. Accordingly, a bulk wave in the thickness-shear mode is effectively excited, and good resonance characteristics can be obtained. More preferably, d/p is about 0.24 or less, for example, and, in this case, more preferable resonant characteristics can be obtained.

Since the acoustic wave device 1 has the structure described above, even when the number of pairs of electrodes 3 and 4 is reduced for size reduction, the Q value is less likely to decrease. This is because the propagation loss is low even when the number of electrode fingers of the reflectors on both sides is reduced. In addition, the reason why the number of electrode fingers described above can be reduced is due to use of a bulk wave in the thickness-shear mode. The difference between a Lamb wave used in the acoustic wave device and the bulk wave in the thickness-shear mode will be described with reference to FIGS. 21A and 21B.

FIG. 21A is a schematic elevational cross-sectional view for describing a Lamb wave propagating through a piezoelectric film of an acoustic wave device as described in Japanese Unexamined Patent Application Publication No. 2012-257019. Here, the wave propagates through the piezoelectric film 201 as indicated by arrows. In the piezoelectric film 201, a first main surface 201a and a second main surface 201b face away from each other, and the thickness direction that connects the first main surface 201a and the second main surface 201b is a Z direction. An X direction is a direction in which the electrode fingers of the IDT electrode are arranged. As illustrated in FIG. 21A, the Lamb wave propagates in the X direction as illustrated in the drawing. The entire piezoelectric film 201 vibrates because of a plate wave, the wave propagates in the X direction. Accordingly, the reflectors are disposed on both sides to obtain resonance characteristics. Therefore, propagation loss of the wave occurs. When an attempt to achieve size reduction is made, that is, when the number of pairs of electrode fingers is reduced, the Q value decreases.

On the other hand, as illustrated in FIG. 21B, since vibration displacement occurs in a thickness-shear direction in the acoustic wave device 1, the wave propagates substantially in the direction connecting the first main surface 2a and the second main surface 2b of the piezoelectric layer 2, that is, in the Z direction, and resonates. That is, the X-direction component of the wave is significantly smaller than the Z-direction component thereof. In addition, since resonance characteristics are obtained by the propagation of the wave in the Z direction, even when the number of electrode fingers of the reflector is reduced, propagation loss is less likely to occur. In addition, even when the number of pairs of electrodes 3 and 4 is reduced to achieve size reduction, the Q value is less likely to decrease.

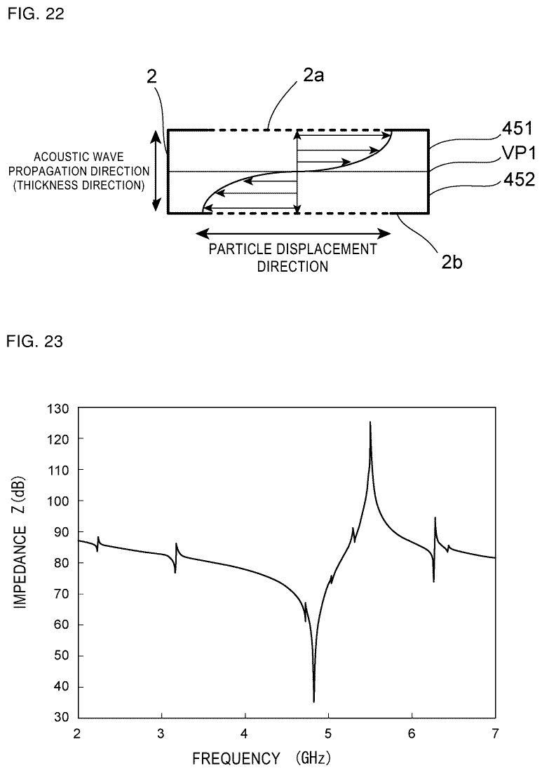

It should be noted that the amplitude direction of a bulk wave in the thickness-shear mode in a first region 451 included in the excitation region C of the piezoelectric layer 2 is opposite to that in a second region 452 included in the excitation region C, as illustrated in FIG. 22. FIG. 22 schematically illustrates a bulk wave when a voltage is applied between the electrode 3 and the electrode 4 such that the potential of the electrode 4 is higher than that of the electrode 3. The first region 451 is the region between the first main surface 2a and a virtual plane VP1, orthogonal to the thickness direction of the piezoelectric layer 2, that divides the piezoelectric layer 2 into two in the excitation region C. The second region 452 is the region between the second main surface 2b and the virtual plane VP1 in the excitation region C.

Although at least one pair of electrodes 3 and 4 is disposed in the acoustic wave device 1 as described above, since the wave does not propagate in the X direction, the number of pairs of electrodes 3 and 4 does not need to be two or more. That is, at least one pair of electrodes only needs to be provided.

For example, the electrode 3 described above is an electrode connected to a hot potential, and the electrode 4 is an electrode connected to a ground potential. However, the electrode 3 may also be connected to the ground potential and the electrode 4 may also be connected to the hot potential. In the present example embodiment, at least one pair of electrodes is connected to the hot potential and the ground potential as described above, and no floating electrode is provided.

FIG. 23 is a diagram illustrating resonance characteristics of the acoustic wave device illustrated in FIG. 20. It should be noted that examples of the design parameters of the acoustic wave device 1 having the resonance characteristics are indicated below.
Piezoelectric layer 2: LiNbO₃ with Euler angles (0°, 0°, 90°), thickness=400 nm.

Length of the region in which the electrode 3 and the electrode 4 overlap each other as viewed in a direction orthogonal to the length direction of the electrode 3 and the electrode 4, that is, the length of the excitation region C=40 μm, the number of pairs of electrodes 3 and 4=21, the center-to-center distance between the electrodes=3 μm, the width of the electrodes 3 and 4=500 nm, d/p=0.133
Insulation layer 7: silicon oxide film with a thickness of 1 μm
Support 8: Si

It should be noted that the length of the excitation region C refers to the dimension of the excitation region C in the length direction of the electrodes 3 and 4.

In the present example embodiment, the inter-electrode distance between a pair of electrodes 3 and 4 is the same among the plurality of pairs. That is, the electrode 3 and the electrode 4 are disposed at an equal pitch.

As is clear from FIG. 23, good resonance characteristics having a fractional bandwidth of about 12.5%, for example, are obtained even though no reflectors are present.

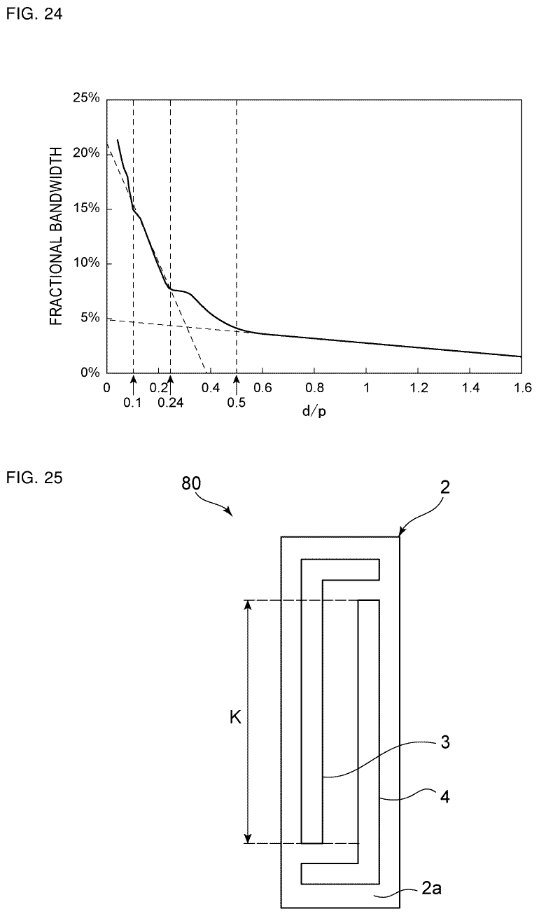

In addition, in the present example embodiment, when the thickness of the piezoelectric layer 2 is d and the center-to-center distance between the electrode 3 and the electrode 4 is p, d/p is about 0.5 or less and more preferably about 0.24 or less, for example, as described above. This will be described with reference to FIG. 24.

A plurality of acoustic wave devices have been obtained in the same manner as the acoustic wave device with the resonance characteristics illustrated in FIG. 23 but d/p is changed. FIG. 24 is a diagram illustrating the relationship between d/p and the fractional bandwidth of the acoustic wave device as a resonator.

As is clear from FIG. 24, when d/p>about 0.5, the fractional bandwidth is less than about 5% even if d/p is adjusted, for example. On the other hand, when d/p≤about 0.5, the fractional bandwidth can be about 5% or more, for example, by d/p being changed within this range, that is, a resonator with a high coupling coefficient can be provided. Alternatively, when d/p is about 0.24 or less, the fractional bandwidth can be increased to about 7% or more, for example. In addition, by d/p being adjusted within this range, a resonator with a wider fractional bandwidth can be obtained, and a resonator with a higher coupling coefficient can be achieved. Accordingly, it was discovered that a resonator with a high coupling coefficient that use a bulk wave in the thickness-shear mode can be formed by d/p being set to about 0.5 or less, for example.

FIG. 25 is a plan view of the acoustic wave device that uses a bulk wave in the thickness-shear mode. In an acoustic wave device 80, a pair of electrodes 3 and 4 is provided on the first main surface 2a of the piezoelectric layer 2. It should be noted that K in FIG. 25 represents the overlap width. As described above, in the acoustic wave device according to the present invention, the number of pairs of electrodes may be one. Even in this case, when d/p is about 0.5 or less, for example, a bulk wave in the thickness-shear mode can be effectively excited.

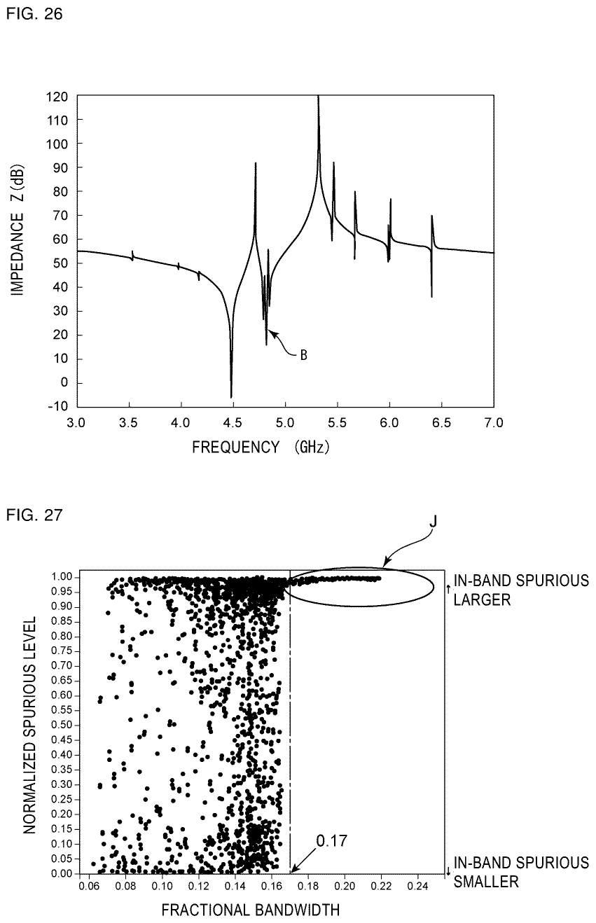

In the acoustic wave device 1, preferably, the metallization ratio MR of any adjacent electrodes 3 and 4 of the plurality of electrodes 3 and 4 with respect to the excitation region C in which the electrodes 3 and 4 overlap each other as viewed in a direction in which the adjacent electrodes 3 and 4 face each other desirably satisfies MR≤about 1.75 (d/p)+0.075, for example. In this case, spurious can be effectively reduced. This will be described with reference to FIGS. 26 and 27. FIG. 26 is a reference diagram illustrating an example of the resonance characteristics of the acoustic wave device 1 described above. The spurious indicated by arrow B appears between the resonant frequency and the anti-resonant frequency. It is assumed that d/p is about 0.08 and the Euler angles of LiNbO₃ are (0°, 0°, 90°), for example. In addition, it is assumed that the metallization ratio MR described above is about 0.35, for example.

The metallization ratio MR will be described with reference to FIG. 19B. In the electrode structure in FIG. 19B, when attention is focused on a pair of electrodes 3 and 4, it is assumed that only this pair of electrodes 3 and 4 is provided. In this case, the portion surrounded by the dotted line is the excitation region C. This excitation region C is the region of the electrode 3 that overlaps the electrode 4, the region of the electrode 4 that overlaps the electrode 3, and the region between the electrode 3 and the electrode 4 in which the electrode 3 and the electrode 4 overlap each other, as viewed in the direction orthogonal to the length direction of the electrodes 3 and 4, that is, in the facing direction. In addition, the ratio of the areas of the electrodes 3 and 4 in the excitation region C to the area of the excitation region C is the metallization ratio MR. That is, the metallization ratio MR is the ratio of the area of the metallization portion to the area of the excitation region C.

It should be noted that, when a plurality of pairs of electrodes are provided, MR may be the ratio of the metallization portions included in all excitation regions to the sum of the areas of the excitation regions.

FIG. 27 is a diagram illustrating the relationship between the fractional bandwidth when many acoustic wave devices are formed according to the present example embodiment and the phase rotation amount of the impedance of spurious normalized by 180 degrees as the level of the spurious. It should be noted that the fractional bandwidth has been adjusted by the film thickness of the piezoelectric layer and the dimensions of the electrodes being changed. In addition, FIG. 27 illustrates the results obtained when a piezoelectric layer made of Z-cut LiNbO₃ is used, but similar trends are also obtained when a piezoelectric layer with a different cut angle is used.

In the region in an ellipse J in FIG. 27, large spurious with a level of about 1.0 appears, for example. As is clear from FIG. 27, when the fractional bandwidth exceeds about 0.17 (that is, about 17%), for example, large spurious with a level of 1 or more appears in the pass band even when parameters of the fractional bandwidth are changed. That is, large spurious indicated by arrow B appears within the band as the resonance characteristics illustrated in FIG. 26. Accordingly, the fractional bandwidth is preferably about 17% or less, for example. In this case, spurious can be reduced by the film thickness of the piezoelectric layer 2 and the dimensions of the electrodes 3 and 4 being adjusted.

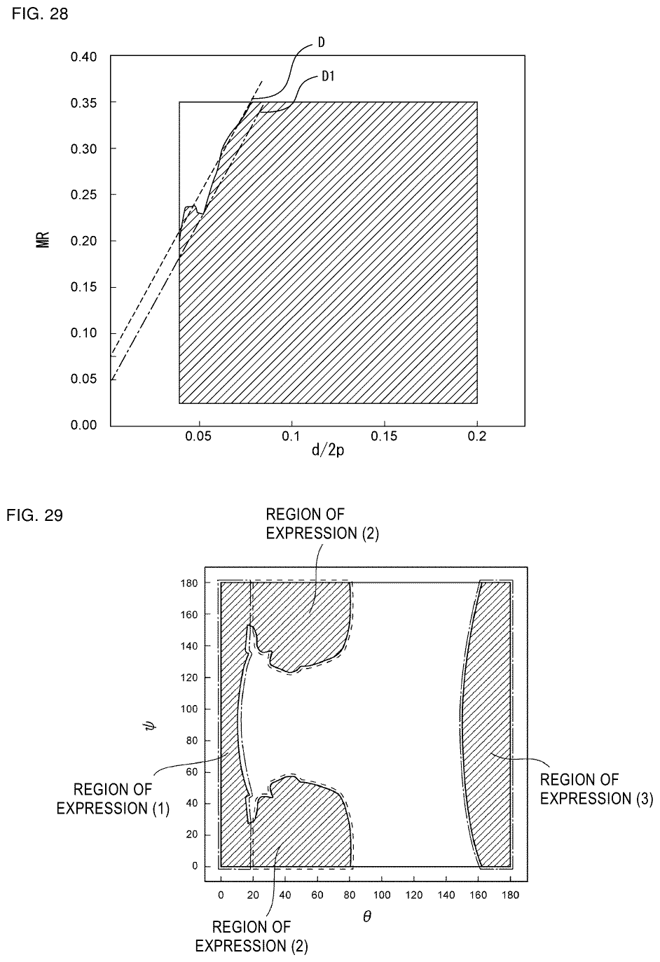

FIG. 28 is a diagram illustrating the relationship between d/2p, the metallization ratio (MR), and the fractional bandwidth. In the acoustic wave device described above, various acoustic wave devices with different d/2p values and MR values were formed, and the fractional bandwidth of each of them was measured. In the hatched region on the right side of a dashed line D in FIG. 28, the fractional bandwidth is about 17% or less, for example. The boundary between the hatched region and the non-hatched region is represented by MR=about 3.5 (d/2p)+0.075, for example. That is, MR=about 1.75 (d/p)+0.075, for example, is satisfied. Accordingly, MR≤about 1.75 (d/p)+0.075 is preferably satisfied, for example. In this case, the fractional bandwidth can be easily set to about 17% or less, for example. The region on the right side of a dot-dash line D1 in FIG. 28 represented by MR=about 3.5 (d/2p)+0.05 is more preferable, for example. That is, when MR≤about 1.75 (d/p)+0.05 is satisfied, the fractional bandwidth can be about 17% or less with greater certainty, for example.

FIG. 29 is a diagram illustrating a map of the fractional bandwidth with respect to Euler angles (0°, e, v) of LiNbO₃ when d/p is infinitely brought close to 0. In the hatched region in FIG. 29, a fractional bandwidth of at least about 5% or more, for example, can be obtained, and the ranges of this region are approximated by expressions (1), (2), and (3).

(0°±10°, 0° to 20°, any given ψ) expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) expression (2)

(0°±10°, [180°−30° (1−(ψ−90)²/8100)^{1/2}] to 180°, any given ψ) expression (3)

Accordingly, in the range of the Euler angles indicated by equation (1), equation (2), or equation (3), it is preferable because the fractional bandwidth can be sufficiently widened. The same applies when the piezoelectric layer 2 is a lithium tantalate layer.

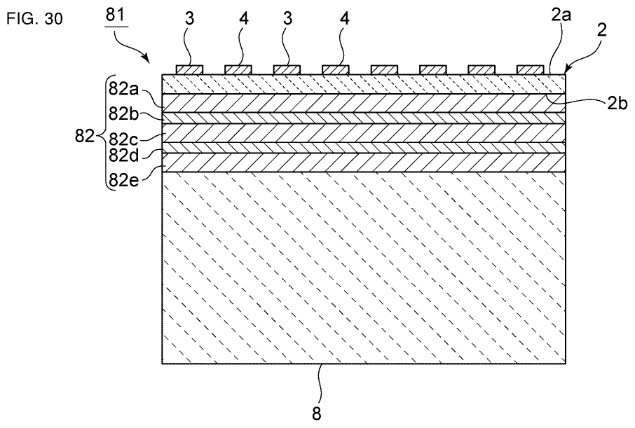

FIG. 30 is an elevational cross-sectional view of the acoustic wave device including an acoustic multilayer film.

In the acoustic wave device 81, an acoustic multilayer film 82 is laminated on the second main surface 2b of the piezoelectric layer 2. The acoustic multilayer film 82 has a laminated structure in which low-acoustic-impedance layers 82a, 82c, and 82e with relatively low acoustic impedance and high-acoustic-impedance layers 82b and 82d with relatively high acoustic impedance are laminated together. When the acoustic multilayer film 82 is used, a bulk wave in the thickness-shear mode can be confined in the piezoelectric layer 2 without using the cavity portion 9 of the acoustic wave device 1. Also in the acoustic wave device 81, resonance characteristics based on a bulk wave of the thickness-shear mode can be obtained by d/p being set to about 0.5 or less, for example. It should be noted that the number of the low-acoustic-impedance layers 82a, 82c, and 82e and the high-acoustic-impedance layers 82b and 82d laminated together in the acoustic multilayer film 82 is not particularly limited. At least one of the high-acoustic-impedance layers 82b and 82d only needs to be disposed further away from the piezoelectric layer 2 than the low-acoustic-impedance layers 82a, 82c, and 82e.

The low-acoustic-impedance layers 82a, 82c, and 82e and the high-acoustic-impedance layers 82b and 82d can be made of appropriate materials as long as the relationship of acoustic impedance described above is satisfied. For example, the material of the low-acoustic-impedance layers 82a, 82c, and 82e may be silicon oxide, silicon oxynitride, or the like. In addition, the material of the high-acoustic-impedance layers 82b and 82d may be alumina, silicon nitride, or a metal.

In the acoustic wave devices according to the first to sixth example embodiments and the individual modifications, the acoustic multilayer film 82 illustrated in FIG. 30 that serves as an acoustic reflection film may be provided between, for example, the support and the piezoelectric layer. Specifically, the support and the piezoelectric film may be disposed such that at least a portion of the support and at least a portion of the piezoelectric film that serves as the piezoelectric film face each other with the acoustic multilayer film 82 therebetween. In this case, a low-acoustic-impedance layer and a high-acoustic-impedance layer only need to be alternately laminated with each other in the acoustic multilayer film 82. The acoustic multilayer film 82 may be an acoustic reflection portion of the acoustic wave device.

In the acoustic wave devices according to the first to sixth example embodiments and the individual modifications that use a bulk wave in the thickness-shear mode, d/p is preferably about 0.5 or less and more preferably about 0.24 or less, for example, as described above. As a result, better resonance characteristics can be obtained. In the overlap region of each of the acoustic wave devices according to the first to sixth example embodiments and the individual modifications that use a bulk wave in the thickness-shear mode, MR≤1.75 (d/p)+0.075 is preferably satisfied as described above. In this case, spurious can be suppressed with greater certainty.

The piezoelectric layer of each of the acoustic wave devices according to the first to sixth example embodiments and the individual modifications that use a bulk wave in the thickness-shear mode is preferably a lithium niobate layer or a lithium tantalate layer. In addition, Euler angles (φ, θ, ψ) of the lithium niobate or lithium tantalate of the piezoelectric layer preferably fall within the range of expression (1), expression (2), or expression (3) described above. In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric substrate that includes:
a support including a support substrate; and
a piezoelectric film including a piezoelectric layer provided on the support; and
an IDT electrode, provided on the piezoelectric layer, that includes:
a first busbar and a second busbar that face each other;
a plurality of first electrode fingers; and
a plurality of second electrode fingers; wherein
an acoustic reflection portion is located at a position at which the support overlaps the IDT electrode in plan view in a direction in which the support and the piezoelectric film are laminated together;
one ends of the plurality of first electrode fingers of the IDT electrode are connected to the first busbar, one ends of the plurality of second electrode fingers are connected to the second busbar, and the plurality of first electrode fingers and the plurality of second electrode fingers are interdigitated with each other;
when a thickness of the piezoelectric film is d and a center-to-center distance between the first and second electrode fingers adjacent to each other is p, d/p is about 0.5 or less;
when a direction in which the first electrode fingers and the second electrode fingers extend is an electrode finger extension direction and a direction orthogonal to the electrode finger extension direction is an electrode finger orthogonal direction, a region in which the first and second electrode fingers adjacent to each other overlap each other in the electrode finger orthogonal direction is an overlap region, and the overlap region includes a middle region and first and second edge regions on both sides of the middle region in the electrode finger extension direction;
a region located between the first edge region and the first busbar is a first gap region, and a region located between the second edge region and the second busbar is a second gap region;
the acoustic wave device further comprising:
a first mass-addition film provided over the first edge region and the first gap region; and
a second mass-addition film provided over the second edge region and the second gap region; wherein
when dimensions of the first mass-addition film and the second mass-addition film in the electrode finger extension direction are lengths of the first mass-addition film and the second mass-addition film, at least one of a pair of the length of the first mass-addition film in the first gap region and the length of the second mass-addition film in the second gap region and a pair of the length of the first mass-addition film in the first edge region and the length of the second mass-addition film in the second edge region differs from each other.

2. The acoustic wave device according to claim 1, wherein, when regions between the first and second electrode fingers are inter-electrode-finger regions, the first mass-addition film is continuously provided so as to overlap the plurality of first electrode fingers, the plurality of second electrode fingers, and the inter-electrode-finger regions in plan view.

3. The acoustic wave device according to claim 1, wherein a plurality of first mass-addition films are provided over the first edge region and the first gap region, the first mass-addition film being one of the plurality of first mass-addition films, and the plurality of first mass-addition films are arranged in the electrode finger orthogonal direction.

4. The acoustic wave device according to claim 3, wherein each of the first mass-addition films is laminated with one electrode finger of the plurality of first electrode fingers and the plurality of second electrode fingers.

5. The acoustic wave device according to claim 1, wherein a sum of the length of the first mass-addition film in the first edge region and the length of the first mass-addition film in the first gap region and a sum of the length of the second mass-addition film in the second edge region and the length of the second mass-addition film in the second gap region differ from each other.

6. The acoustic wave device according to claim 1, wherein a sum of the length of the first mass-addition film in the first edge region and the length of the first mass-addition film in the first gap region and a sum of the length of the second mass-addition film in the second edge region and the length of the second mass-addition film in the second gap region are the same as each other.

7. The acoustic wave device according to claim 1, wherein the piezoelectric layer, the first electrode fingers, and the first mass-addition film are laminated together in this order in a portion in which the first mass-addition film and the first electrode fingers are laminated together.

8. The acoustic wave device according to claim 1, wherein the piezoelectric layer, the first mass-addition film, and the first electrode fingers are laminated together in this order in a portion in which the first mass-addition film and the first electrode fingers are laminated together.

9. The acoustic wave device according to claim 1, wherein the plurality of first electrode fingers includes widened portions located in the second edge region, and a width of the first electrode fingers in the widened portions is greater than a width of the first electrode fingers in the middle region.

10. The acoustic wave device according to claim 1, wherein
a dielectric film is provided on the piezoelectric layer to cover the IDT electrode; and
the piezoelectric layer, the dielectric film, and the first mass-addition film are laminated together.

11. The acoustic wave device according to claim 10, wherein the dielectric film is made of silicon oxide.

12. The acoustic wave device according to claim 10, wherein
the piezoelectric layer, the dielectric film, and the first mass-addition film are laminated together in this order; and
the first mass-addition film is made of a metal.

13. The acoustic wave device according to claim 1, wherein the first mass-addition film and the second mass-addition film are made of at least one of silicon oxide, tantalum oxide, niobium oxide, tungsten oxide, or hafnium oxide.

14. The acoustic wave device according to claim 1, wherein d/p is about 0.24 or less.

15. The acoustic wave device according to claim 1, wherein
a region between middle positions of the first and second electrode fingers adjacent to each other in the electrode finger orthogonal direction, in which the first and second electrode fingers adjacent to each other overlap each other in the electrode finger orthogonal direction, is an excitation region; and
MR≤about 1.75 (d/p)+0.075 is satisfied where MR is a metallization ratio of the plurality of electrode fingers to the excitation region.

16. The acoustic wave device according to claim 1, wherein the piezoelectric layer is made of lithium niobate.

17. The acoustic wave device according to claim 16, wherein
Euler angles (φ, θ, ψ) of the lithium niobate of the piezoelectric layer fall within a range represented by expression (1), expression (2), or expression (3):
(0°±10°, 0° to 20°, any given ψ) expression (1)
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) expression (2)
(0°±10°, [180°−30° (1−(ψ−90)²/8100)^{1/2}] to 180°, any given ψ) expression (3).

18. The acoustic wave device according to claim 1, wherein the acoustic reflection portion is a cavity portion, and the support and the piezoelectric film are located such that a portion of the support and a portion of the piezoelectric film face each other with the cavity portion therebetween.

19. The acoustic wave device according to claim 1, wherein the acoustic reflection portion is an acoustic reflection film including a high-acoustic-impedance layer with a relatively high acoustic impedance and a low-acoustic-impedance layer with a relatively low acoustic impedance, and the support and the piezoelectric film are located such that at least a portion of the support and at least a portion of the piezoelectric film face each other with the acoustic reflection film therebetween.

20. The acoustic wave device according to claim 1, wherein the acoustic wave device is an acoustic wave resonator capable of using a bulk wave in a thickness-shear mode, a multiplexer, or a filter device include a plurality of acoustic wave resonators.
